(19) United States
(12) Patent Application Publication
(10) Pub. No.: US 2012/0045982 A1
(43) Pub. Date: Feb. 23, 2012

(54) CONTAINER DATA CENTER

(75) Inventor: YAO-TING CHANG, Tu-Cheng (TW)

(73) Assignee: HON HAI PRECISION INDUSTRY CO., LTD., Tu-Cheng (TW)

(21) Appl. No.: 12/894,167

(22) Filed: Sep. 30, 2010

(30) Foreign Application Priority Data
Aug. 18, 2010 (TW) 99127514

(51) Int. Cl. H05K 5/02

(52) U.S. Cl. 454/184

(57) ABSTRACT

A container data center includes a container, a partition member received in the container, and a number of non-powered turbines installed on the top wall of the container. The container includes a top wall, a bottom wall opposite to the top wall, and a sidewall connected between the top wall and the bottom wall. The sidewall defines a number of vents. The partition member includes a first partition plate adjacent to the top wall of the container and a second partition plate extending down from sides of the first partition plate to connect to the bottom wall of the container. An air channel is formed between the partition member and the container. The cool air outside the container can flow into the air channel through the number of vents, and the hot air of the air channel flows out of the container through the number of non-powered turbines.

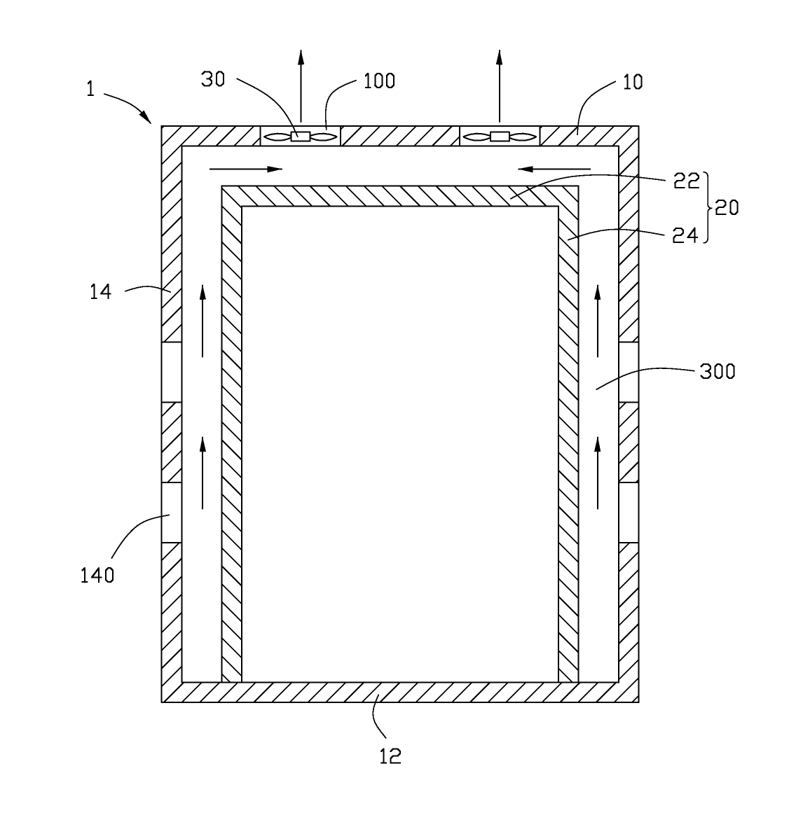

### BACKGROUND

1. Technical Field

The present disclosure relates to a container data center.

2. Description of Related Art

If container data centers are exposed to sunlight for a long time, the temperature inside of the container data centers may become too high. Under such circumstances, more power is needed to dissipate the heat.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

The FIGURE is a schematic, sectional view of an exemplary embodiment of a container data center.

### DETAILED DESCRIPTION

The present disclosure, including the accompanying drawing, is illustrated by way of examples and not by way of limitation. It should be noted that references to “an” or “one” embodiment in this disclosure are not necessarily to the same embodiment, and such references mean at least one.

Referring to the FIGURE, an exemplary embodiment of a container data center includes a container 1. The container 1 includes a top wall 10, a bottom wall 12 substantially parallel and opposite to the top wall 10, and a sidewall 14 perpendicularly connected between the top wall 10 and the bottom wall 12, thereby forming a first closed receiving space. The top wall 10 defines a number of receiving spaces 100. Each receiving space 100 can receive a non-powered turbine 30. The sidewall 14 defines a number of vents 140.

A partition member 20 is received in the container 1. The partition member 20 is a substantially U-shape The partition member 20 includes a first partition plate 22 adjacent and substantially parallel to the top wall 10, and a second partition plate 24 perpendicularly extending down along the sides of the top wall 10, adjacent and substantially parallel to the sidewall 14. The distal ends of the second partition plate 24 are connected to the bottom wall 12. The first and second partition plates 22 and 24, and the bottom wall 12 form a second closed receiving space. An air channel 300 is defined between the container 1 and the partition member 20. The container 1 and the partition member 20 are made of the same material. The electronic elements of the container data center, such as a number of servers, are received in the second closed receiving space of the partition member 20.

The non-powered turbines 30 can take advantage of differences between indoor temperatures and outdoor temperatures for changing the air. For example, when the indoor temperature of the air channel 300 is higher than the outdoor temperature, the indoor hot air flows outdoors through the non-powered turbines 30.

When the container data center is exposed for a long time to the sunlight, the temperature inside the container 1 rises, which causes the temperature of the air channel 300 to be higher than the temperature outside the container 1. Thus, the hot air of the air channel 300 flows in the air channel 300, along the arrows shown in the figure, and flows out of the container 1 through the non-powered turbines 30, and the cool air outside the container 1 flows into the air channel 300 through the vents 140. This can keep the hot air of the air channel 300 from flowing into the inside of the partition member 20 and reduce energy consumption.

It is to be understood, however, that even though numerous characteristics and advantages of the embodiments have been set forth in the foregoing description, together with details of the structure and function of the embodiments, the present disclosure is illustrative only, and changes may be made in details, especially in matters of shape, size, and arrangement of parts within the principles of the embodiments to the full extent indicated by the broad general meaning of the terms in which the appended claims are expressed.

What is claimed is:

1. A container data center comprising:
a container comprising a top wall, a bottom wall opposite to the top wall, and a sidewall connected between the top wall and the bottom wall, thereby the top wall, the sidewall, and the bottom wall, wherein the sidewall defines a plurality of vents;
a partition member received in the container, the partition member comprising a first partition plate adjacent to the top wall of the container and a second partition plate extending down along the sides of the first partition plate to connect to the bottom wall of the container, thereby the first and second partition plates, and the bottom wall of the container forming; and
a plurality of non-powered turbines installed on the top wall of the container;
wherein an air channel is formed between the partition member and the container, the cool air outside the container can flow into the air channel through the plurality of vents, and the hot air of the air channel flows out of the container through the plurality of non-powered turbines.

2. The container data center of claim 1, wherein the first partition plate is parallel to the top wall.

3. The container data center of claim 1, wherein the container and the partition member are made of the same material.

4. The container data center of claim 1, wherein the top wall of the container defines a plurality of receiving spaces, each of the receiving spaces receives a non-powered turbine.
